(19) United States
(12) Patent Application Publication
(10) Pub. No.: US 2023/0008050 A1
(43) Pub. Date: Jan. 12, 2023

(54) IMAGE SENSOR

(71) Applicant: DB HITEK CO., LTD., Seoul (KR)

(72) Inventors: Jong Min KIM, Seoul (KR); Dong Jun OH, Seoul (KR)

(21) Appl. No.: 17/810,074

(22) Filed: Jun. 30, 2022

(30) Foreign Application Priority Data
Jul. 7, 2021 (KR) 10-2021-0089094

(51) Int. Cl. H01L 27/146

(52) U.S. Cl. CPC H01L 27/14623; H01L 27/14612; H01L 27/14636; H01L 27/1463

(57) ABSTRACT

An image sensor includes at least one image cell having a photodiode disposed in a substrate, a charge storage region disposed in the substrate to be spaced apart from the photodiode, a transfer gate electrode disposed on a channel region between the photodiode and the charge storage region to transfer a charge from the photodiode to the charge storage region, and a dummy pattern disposed on the substrate and configured to inhibit light from being introduced into the charge storage region from an adjacent image cell.

### CROSS-REFERENCE TO RELATED APPLICATION

This application claims the priority benefit of Korean Patent Application No. 10-2021-0089094, filed on Jul. 7, 2021, and all the benefits accruing therefrom under 35 U.S.C. § 119, the contents of which are incorporated by reference in their entirety.

### TECHNICAL FIELD

The present disclosure relates to an image sensor. More specifically, the present disclosure relates to an image sensor including a photodiode and a charge storage region formed in a substrate.

### BACKGROUND

In general, an image sensor is a semiconductor device that converts an optical image into electrical signals, and may be classified or categorized as a Charge Coupled Device (CCD) or a Complementary Metal Oxide Semiconductor (CMOS) Image Sensor (CIS). The CIS may include unit pixels, each including a photodiode and MOS transistors. The CIS sequentially detects the electrical signals of the unit pixels using a switching method, thereby forming an image.

The photodiode may include a charge accumulation region in which charges generated by the incident light are accumulated. For example, the photodiode may include an N-type impurity region in which electrons are accumulated, and a P-type impurity region serving as a pinning region for reducing dark current may be formed on the N-type impurity region.

As an example, the image sensor may include a transfer gate electrode formed on a substrate, and the electrons may be transferred from the charge accumulation region to a charge detection region, for example, a floating diffusion region, through a channel region below the transfer gate electrode. As another example, an image sensor using a global shutter method may include a charge storage region for storing the electrons between the charge accumulation region and the floating diffusion region. In such case, transfer gate electrodes may be formed on surface portions of the substrate among the charge accumulation region, the charge storage region and the floating diffusion region.

However, when light enters the charge storage region from an adjacent image cell, electrons may be generated in the charge storage region by the light, and operating characteristics of the image sensor may be deteriorated by the electrons.

### SUMMARY

The present disclosure provides an image sensor capable of inhibiting light entering a charge storage region from an adjacent image cell.

In accordance with an aspect of the present disclosure, an image sensor may include at least one image cell having a photodiode disposed in a substrate, a charge storage region disposed in the substrate to be spaced apart from the photodiode, a transfer gate electrode disposed on a channel region between the photodiode and the charge storage region to transfer a charge from the photodiode to the charge storage region, and a dummy pattern disposed on the substrate and configured to inhibit light from being introduced into the charge storage region from an adjacent image cell.

In accordance with some embodiments of the present disclosure, the dummy pattern may be disposed on a surface portion of the substrate between the charge storage region and a photodiode of the adjacent image cell, and may be made of the same material as the transfer gate electrode.

In accordance with some embodiments of the present disclosure, the dummy pattern may include polysilicon.

In accordance with some embodiments of the present disclosure, the image sensor may further include an insulating layer disposed on the substrate, the transfer gate electrode and the dummy pattern, and a light shield layer disposed on the insulating layer and configured to inhibit light from entering the charge storage region.

In accordance with some embodiments of the present disclosure, the image sensor may further include a light shield pattern disposed between the dummy pattern and the light shield layer and configured to pass through the insulating layer.

In accordance with some embodiments of the present disclosure, the image sensor may further include a second light shield pattern extending from a first edge portion of the light shield layer adjacent to the adjacent image cell toward the substrate.

In accordance with some embodiments of the present disclosure, the insulating layer may include a first oxide layer disposed on the substrate, the transfer gate electrode, and the dummy pattern, a nitride layer disposed on the first oxide layer, and a second oxide layer disposed on the nitride layer. In such case, the second light shield pattern may be configured to pass through the second oxide layer.

In accordance with some embodiments of the present disclosure, the image sensor may further include an anti-reflective layer disposed between the substrate and the insulating layer, and the second light shield pattern may be configured to pass through the insulating layer.

In accordance with some embodiments of the present disclosure, the image sensor may further include a third light shield pattern extending from a second edge portion of the light shield layer adjacent to the photodiode toward the substrate.

In accordance with some embodiments of the present disclosure, the image sensor may further include a second light shield pattern disposed between the dummy pattern and the light shield layer and configured to pass through the insulating layer.

In accordance with some embodiments of the present disclosure, the image sensor may further include a light shield pattern disposed between the dummy pattern and a first edge portion of the light shield layer adjacent to the adjacent image cell and configured to pass through the insulating layer.

In accordance with some embodiments of the present disclosure, the image sensor may further include a second insulating layer disposed on the insulating layer and the light shield layer, interlayer insulating layers disposed on the second insulating layer, metal wiring layers disposed among the interlayer insulating layers, and a light guide pattern passing through the interlayer insulating layers and corresponding to the photodiode.

In accordance with some embodiments of the present disclosure, the image sensor may further include an etch stop layer disposed on the second insulating layer, and the light guide pattern may be disposed on the etch stop layer.

In accordance with some embodiments of the present disclosure, the image sensor may further include an isolation region disposed in a surface portion of the substrate between the charge storage region and a photodiode of the adjacent image cell.

In accordance with some embodiments of the present disclosure, the dummy pattern may be disposed on the isolation region.

In accordance with some embodiments of the present disclosure, the dummy pattern may include a lower pattern disposed in the isolation region, and an upper pattern disposed on the lower pattern.

In accordance with some embodiments of the present disclosure, the image sensor may further include a second dummy pattern disposed on the charge storage region and configured to inhibit light from entering the charge storage region, and an insulating layer disposed between the charge storage region and the second dummy pattern and configured to electrically insulate the charge storage region from the second dummy pattern.

In accordance with some embodiments of the present disclosure, the second dummy pattern may be made of the same material as the dummy pattern.

In accordance with another aspect of the present disclosure, an image sensor may include a photodiode disposed in a substrate, a charge storage region disposed in the substrate to be spaced apart from the photodiode, a transfer gate electrode disposed on a channel region between the photodiode and the charge storage region to transfer a charge from the photodiode to the charge storage region, a light absorption pattern disposed on the substrate and configured to absorb light directed to the charge storage region from an adjacent image cell, and a light reflection pattern disposed on the light absorption pattern and configured to reflect the light.

In accordance with still another aspect of the present disclosure, an image sensor may include a photodiode disposed in a substrate, a charge storage region disposed in the substrate to be spaced apart from the photodiode, a transfer gate electrode disposed on a channel region between the photodiode and the charge storage region to transfer a charge from the photodiode to the charge storage region, an isolation region disposed in a surface portion of the substrate between the charge storage region and a photodiode of an adjacent image cell, an insulating layer disposed on the substrate, a light shield layer disposed on the insulating layer and configured to inhibit light from entering the charge storage region, a first light shield pattern disposed between an edge portion of the light shield layer and an edge portion of the photodiode of the adjacent image cell and configured to inhibit light from entering the charge storage region from the adjacent image cell, and a second light shield pattern disposed between the light shield layer and the isolation region and configured to inhibit light from entering the charge storage region from the adjacent image cell.

In accordance with some embodiments of the present disclosure, the image sensor may further include an anti-reflective layer disposed between the substrate and the insulating layer. In such case, the first light shield pattern and the second light shield pattern may pass through the insulating layer and may be disposed on the anti-reflective layer.

In accordance with some embodiments of the present disclosure, the insulating layer may include a first oxide layer disposed on the substrate, a nitride layer disposed on the first oxide layer, and a second oxide layer disposed on the nitride layer. In such case, the first light shield pattern and the second light shield pattern may pass through the second oxide layer and may be disposed on the nitride layer.

In accordance with still another aspect of the present disclosure, an image sensor may include a photodiode disposed in a substrate, a charge storage region disposed in the substrate to be spaced apart from the photodiode, a transfer gate electrode disposed on a channel region between the photodiode and the charge storage region to transfer a charge from the photodiode to the charge storage region, an isolation region disposed in a surface portion of the substrate between the charge storage region and a photodiode of an adjacent image cell, an insulating layer disposed on the substrate, a light shield layer disposed on the insulating layer and configured to inhibit light from entering the charge storage region, and a light shield pattern disposed between the substrate and the light shield layer and configured to inhibit light from entering the charge storage region from the adjacent image cell.

In accordance with some embodiments of the present disclosure, a portion of the light shield pattern may be disposed between the light shield layer and an edge portion of the photodiode of the adjacent image cell, and another portion of the light shield pattern may be disposed between the light shield layer and the isolation region.

In accordance with some embodiments of the present disclosure, the image sensor may further include an anti-reflective layer disposed between the substrate and the insulating layer, and the light shield pattern may pass through the insulating layer and may be disposed on the anti-reflective layer.

In accordance with some embodiments of the present disclosure, the insulating layer may include a first oxide layer disposed on the substrate, a nitride layer disposed on the first oxide layer, and a second oxide layer disposed on the nitride layer. In such case, the light shield pattern may pass through the second oxide layer and may be disposed on the nitride layer.

In accordance with the embodiments of the present disclosure as described above, the light entering the charge storage region from the adjacent image cell may be reduced by the dummy pattern. Accordingly, the dynamic range, crosstalk, and parasitic light sensitivity of the image sensor may be significantly improved.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic cross-sectional view illustrating an image sensor in accordance with an embodiment of the present disclosure;

FIG. 2 is a schematic enlarged cross-sectional view illustrating a dummy pattern, a light shield pattern, and a second light shield pattern as shown in FIG. 1;

FIG. 3 is a schematic plan view illustrating a photodiode, a charge storage region and a transfer gate electrode as shown in FIG. 1;

FIG. 4 is a schematic enlarged cross-sectional view illustrating another example of a dummy pattern, a light shield pattern and a second light shield pattern in accordance with an embodiment of the present disclosure;

FIG. 5 is a schematic enlarged cross-sectional view illustrating still another example of a dummy pattern, a light shield pattern and a second light shield pattern in accordance with an embodiment of the present disclosure;

FIG. 6 is a schematic enlarged cross-sectional view illustrating still another example of a second light shield pattern in accordance with an embodiment of the present disclosure

FIG. 7 is a schematic enlarged cross-sectional view illustrating still another example of a dummy pattern as shown in accordance with an embodiment of the present disclosure;

FIG. 8 is a schematic enlarged cross-sectional view illustrating still another example of a light shield pattern and a second light shield pattern in accordance with an embodiment of the present disclosure;

FIG. 9 is a schematic enlarged cross-sectional view illustrating still another example of a light shield pattern and a second light shield pattern in accordance with an embodiment of the present disclosure;

FIG. 10 is a schematic enlarged cross-sectional view illustrating still another example of a light shield pattern in accordance with an embodiment of the present disclosure; and

FIG. 11 is a schematic enlarged cross-sectional view illustrating still another example of a light shield pattern in accordance with an embodiment of the present disclosure.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present disclosure are described in more detail with reference to the accompanying drawings. However, the present disclosure is not limited to the embodiments described below and is implemented in various other forms. Embodiments below are not provided to fully complete the present disclosure but rather are provided to fully convey the range of the present disclosure to those skilled in the art.

In the specification, when one component is referred to as being on or connected to another component or layer, it can be directly on or connected to the other component or layer, or an intervening component or layer may also be present. In contrast, it will be understood that when one component is referred to as directly being on or directly connected to another component or layer, it means that no intervening component is present. Also, though terms like a first, a second, and a third are used to describe various regions and layers in various embodiments of the present disclosure, the numbers or arrangements of the regions and the layers are not limited to these terms.

Terminologies used below are used to merely describe specific embodiments, but do not limit the present disclosure. Additionally, unless otherwise defined here, all the terms including technical or scientific terms, may have the same meaning that is generally understood by those skilled in the art.

Embodiments of the present disclosure are described with reference to schematic drawings of idealized embodiments. Accordingly, changes in manufacturing methods and/or allowable errors may be expected from the forms of the drawings. Accordingly, embodiments of the present disclosure are not described being limited to the specific forms or areas in the drawings, and include the deviations of the forms. The areas may be entirely schematic, and their forms may not describe or depict accurate forms or structures in any given area, and are not intended to limit the scope of the present disclosure.

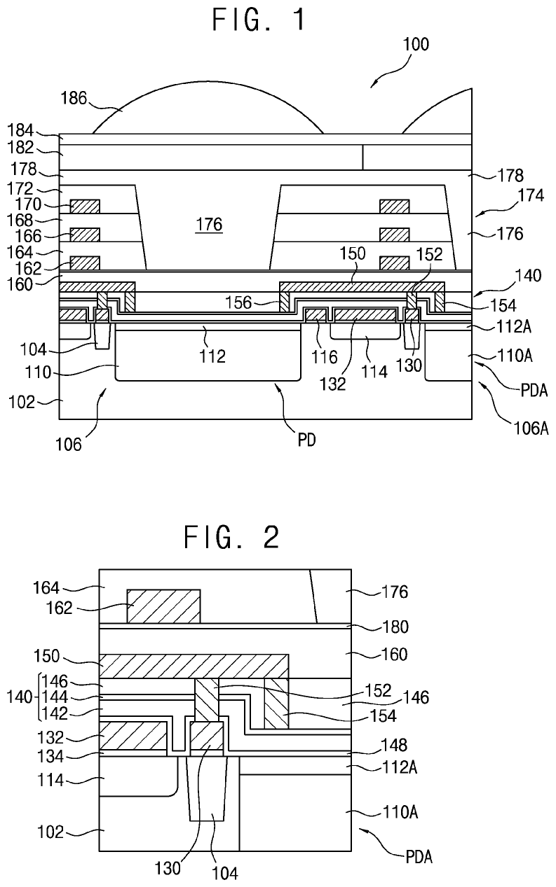

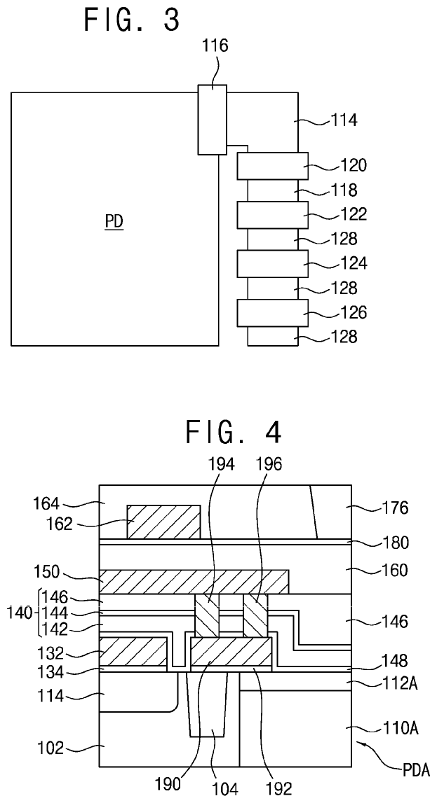

FIG. 1 is a schematic cross-sectional view illustrating an image sensor in accordance with an embodiment of the present disclosure, FIG. 2 is a schematic enlarged cross-sectional view illustrating a dummy pattern, a light shield pattern, and a second light shield pattern as shown in FIG. 1, and FIG. 3 is a schematic plan view illustrating a photodiode, a charge storage region and a transfer gate electrode as shown in FIG. 1.

Referring to FIGS. 1 to 3, an image sensor 100, in accordance with an embodiment of the present disclosure, may include a plurality of image cells 106, and isolation regions 104 for electrically isolating the image cells 106 with one another. Each of the image cells 106 may include a photodiode PD disposed in a substrate 102, a charge storage region 114 disposed in the substrate 102 to be spaced apart from the photodiode PD, and a transfer gate electrode 116 disposed on a channel region between the photodiode PD and the charge storage region 114 to transfer a charge from the photodiode PD to the charge storage region 114. The photodiode PD may include a charge accumulation region 110 formed in the substrate 102 and a pinning layer 112 formed on the charge accumulation region 110. In particular, the transfer gate electrode 116 may be used to move charges accumulated in the charge accumulation region 110 to the charge storage region 114.

The substrate 102 may have a first conductivity type, and the charge accumulation region 110 may have a second conductivity type. For example, a P-type substrate may be used as the substrate 102, and an N-type impurity diffusion region may be used as the charge accumulation region 110. Further, the charge storage region 114 may have the second conductivity type. For example, an N-type impurity diffusion region may be used as the charge storage region 114. Alternatively, a P-type epitaxial layer (not shown) may be formed on the substrate 102. In such cases, the charge accumulation region 110 and the charge storage region 114 may be formed in the P-type epitaxial layer.

A pinning layer 112 having the first conductivity type may be formed on the charge accumulation region 110. For example, a P-type impurity diffusion region may be used as the pinning layer 112. That is, the image sensor 100 may include a pinned photodiode PD including the charge accumulation region 110 and the pinning layer 112.

As shown in FIG. 3, the image sensor 100 may include a floating diffusion region 118 spaced apart from the charge storage region 114, and a second transfer gate electrode 120 may be formed on a second channel region between the charge storage region 114 and the floating diffusion region 118. In addition, the image sensor 100 may include a reset gate electrode 122, a source follower gate electrode 124, and a selection gate electrode 126, and impurity diffusion regions 128 serving as source/drain regions may be formed in surface portions of the substrate 102 adjacent to the reset gate electrode 122, the source follower gate electrode 124, and the selection gate electrode 126. Further, gate insulating layers made of silicon oxide may be formed between the electrodes 116, 120, 122, 124 and 126, and the substrate 102.

In accordance with an embodiment of the present disclosure, the image sensor 100 may include a dummy pattern 130 disposed on the substrate 102 and configured to inhibit light from being introduced into the charge storage region 114 from an adjacent image cell 106A. Specifically, the dummy pattern 130 may be formed on a surface portion of the substrate 102 between the charge storage region 114 and a photodiode PDA of the adjacent image cell 106A. In this case, the photodiode PDA of the adjacent image cell 106A may include a charge accumulation region 110A and a pinning layer 112A.

The dummy pattern 130 may be formed of the same material as the transfer gate electrode 116 and simultaneously with the transfer gate electrode 116. For example, the dummy pattern 130 and the transfer gate electrode 116 may be made of polysilicon doped with impurities, and the light from the adjacent image cell 106A toward the charge storage region 114 may be absorbed by the dummy pattern 130. That is, the dummy pattern 130 may function as a light absorption pattern for absorbing the light, thereby preventing the light from being introduced into the charge storage region 114. In embodiments, after forming a silicon oxide layer and an impurity-doped polysilicon layer on the substrate 102, the transfer gate electrode 116 and the dummy pattern 130 may be formed by patterning the polysilicon layer and the silicon oxide layer.

Further, a second dummy pattern 132 for inhibiting light from being introduced into the charge storage region 114 may be formed on the charge storage region 114. For example, the second dummy pattern 132 may be formed of the same material as the transfer gate electrode 116 and simultaneously with the transfer gate electrode 116. As shown in FIG. 2, an insulating layer 134 such as a silicon oxide layer may be formed between the second dummy pattern 132 and the charge storage region 114, and the second dummy pattern 132 and the charge storage region 114 may be electrically insulated from each other by the insulating layer 134.

An insulating layer 140 may be formed on the substrate 102, the transfer gate electrode 116, the dummy pattern 130, and the second dummy pattern 132. The insulating layer 140 may include a first oxide layer 142 formed on the substrate 102, the transfer gate electrode 116, the dummy pattern 130, and the second dummy pattern 132, a nitride layer 144 formed on the first oxide layer 142, and a second oxide layer 146 formed on the nitride layer 144. For example, the insulating layer 140 may include a first silicon oxide layer 142 formed on the substrate 102, the transfer gate electrode 116, the dummy pattern 130, and the second dummy pattern 132, a silicon nitride layer 144 formed on the first silicon oxide layer 142, and a second silicon oxide layer 146 formed on the silicon nitride layer 144. Further, an anti-reflective layer 148 may be formed between the substrate 102 and the insulating layer 140. In embodiments, the anti-reflective layer 148 may be formed of silicon nitride.

A light shield layer 150 for inhibiting light from entering the charge storage region 114 may be formed on the insulating layer 140. The light shield layer 150 may be made of a metal, for example, aluminum. In particular, a light shield pattern 152 penetrating the insulating layer 140 may be formed between the dummy pattern 130 and the light shield layer 150. The light shield pattern 152 may be formed of a metal, for example, tungsten or copper. Accordingly, light from the adjacent image cell 106A flowing toward the charge storage region 114 may be reflected by the light shield pattern 152. That is, the light shield pattern 152 may function as a light reflection pattern. In embodiments, an isolation region 104 may be formed between the charge storage region 114 and the photodiode PDA of the adjacent image cell 106A, and the dummy pattern 130 may be formed on the isolation region 104. Further, the light shield pattern 152 may be formed on the dummy pattern 130, and the light shield layer 150 may be formed on the insulating layer 140 and the light shield pattern 152.

In accordance with an embodiment of the present disclosure, as shown in FIG. 1, the image sensor 100 may include a second light shield pattern 154 extending from a first edge portion of the light shield layer 150 adjacent to the adjacent image cell 106A toward the substrate 102, and a third light shield pattern 156 extending from a second edge portion of the light shield layer 150 adjacent to the photodiode PD toward the substrate 102. For example, the second and third light shield patterns 154 and 156 may be formed to pass through the second silicon oxide layer 146. Further, the second and third light shield patterns 154 and 156 may be made of the same material as the light shield pattern 152. For example, the second and third light shield patterns 154 and 156 may be formed of a metal such as tungsten or copper. In such cases, the silicon nitride layer 144 may function as an etch stop layer in an anisotropic etching process for forming the second and third light shield patterns 154 and 156.

A second insulating layer 160 may be formed on the insulating layer 140 and the light shield layer 150. In embodiments, a silicon oxide layer may be used as the second insulating layer 160. Further, a plurality of metal wiring layers 162, 166 and 170, and interlayer insulating layers 164, 168 and 172 may be formed on the second insulating layer 160. For example, a first metal wiring layer 162 may be formed on the second insulating layer 160, and a first interlayer insulating layer 164 may be formed on the second insulating layer 160 and the first metal wiring layer 162. A second metal wiring layer 166 may be formed on the first interlayer insulating layer 164, and a second interlayer insulating layer 168 may be formed on the first interlayer insulating layer 164 and the second metal wiring layer 166. A third metal wiring layer 170 may be formed on the second interlayer insulating layer 168, and a third interlayer insulating layer 172 may be formed on the second interlayer insulating layer 168 and the third metal wiring layer 170.

In accordance with an embodiment of the present disclosure, the image sensor 100 may include a light guide pattern layer 174 passing through the interlayer insulating layers 164, 168 and 172. Specifically, the light guide pattern layer 174 may include light guide patterns 176 passing through the interlayer insulating layers 164, 168 and 172, and a planarization layer 178 formed on the third interlayer insulating layer 172 and the light guide patterns 176. For example, the light guide pattern layer 174 may be formed of a dielectric material having a refractive index greater than that of silicon oxide forming the interlayer insulating layers 164, 168 and 172.

An etch stop layer 180 made of silicon nitride may be formed on the second insulating layer 160, as shown in FIG. 2. In embodiments, in an anisotropic etching process for forming the light guide patterns 176, the interlayer insulating layers 164, 168 and 172 may be partially removed until the etch stop layer 180 is exposed, and the light guide patterns 176 may be formed in through holes formed by the anisotropic etching process. As a result, the light guide patterns 176 may be formed on the etch stop layer 180.

Alternatively, although not shown, the light guide patterns 176 may extend to the silicon nitride layer 144. That is, in an anisotropic etching process for forming the light guide patterns 176, the interlayer insulating layers 164, 168 and 172, the second insulating layer 160, and the second silicon oxide layer 146 may be partially removed until the silicon nitride layer 144 is exposed. In such case, in the anisotropic etching process, the silicon nitride layer 144 may be used as an etch stop layer, and the etch stop layer 180 may be omitted. The light guide patterns 176 may be formed on the silicon nitride layer 144 through the interlayer insulating layers 164, 168 and 172, the second insulating layer 160, and the second silicon oxide layer 146, thereby reducing a distance between the pinned photodiodes PD and the light guide patterns 176.

The light guide patterns 176 may be arranged to correspond to the charge accumulation regions 110, and a color filter layer 182 including a plurality of color filters may be formed on the light guide pattern layer 174. A second planarization layer 184 may be formed on the color filter layer 182, and a microlens array 186 may be formed on the second planarization layer 184.

In accordance with the embodiment of the present disclosure as described above, the light flowing from the adjacent image cell 106A toward the charge storage region 114 may be blocked by the second light shield pattern 154. Further, the light directed to the charge storage region 114 from between the second light shield pattern 154 and the substrate 102 may be blocked by the dummy pattern 130 and the light shield pattern 152. Accordingly, the light entering the charge storage region 114 may be significantly reduced, and thus, the dynamic range, crosstalk, and parasitic light sensitivity of the image sensor 100 may be greatly improved.

FIG. 4 is a schematic enlarged cross-sectional view illustrating another example of the dummy pattern, the light shield pattern and the second light shield pattern according to embodiments.

Referring to FIG. 4, a dummy pattern 190 having a large area (relative to, for example, dummy pattern 130 as depicted and described with respect to FIG. 2) may be formed on a surface portion of the substrate 102 between the adjacent image cell 106A and the charge storage region 114. In embodiments, the dummy pattern 190 may include polysilicon to absorb light directed to the charge storage region 114. Particularly, a portion of the dummy pattern 190 may be disposed on an edge portion of the pinning layer 112A of the adjacent image cell 106A. In such cases, an insulating layer 192 such as a silicon oxide layer may be formed between the dummy pattern 190 and the pinning layer 112A for electrical insulation between the dummy pattern 190 and the pinning layer 112A.

In addition, a light shield pattern 194 and a second light shield pattern 196 may be formed between the dummy pattern 190 and the light shield layer 150. The light shield pattern 194 and the second light shield pattern 196 may be formed to pass through the insulating layer 140. That is, the light shield layer 150 may be formed on the second silicon oxide layer 146, the light shield pattern 194, and the second light shield pattern 196.

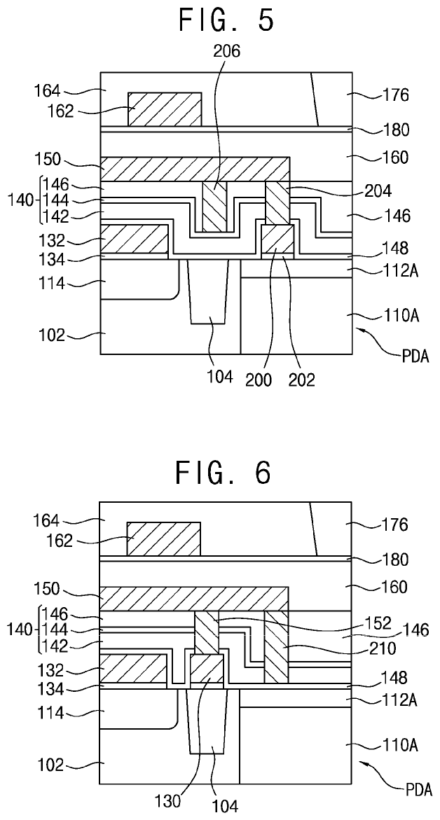

FIG. 5 is a schematic enlarged cross-sectional view illustrating still another example of the dummy pattern, the light shield pattern and the second light shield pattern according to an embodiment of the present disclosure.

Referring to FIG. 5, a dummy pattern 200 may be formed on an edge portion of the photodiode PDA of the adjacent image cell 106A, that is, on an edge portion of the pinning layer 112A of the adjacent image cell 106A. Further, a light shield pattern 204 may be formed to pass through the insulating layer 140 between the dummy pattern 200 and a first edge portion of the light shield layer 150 adjacent to the adjacent image cell 106A. In this case, an insulating layer 202 such as a silicon oxide layer may be formed between the dummy pattern 200 and the pinning layer 112A of the adjacent image cell 106A for electrical insulation between the dummy pattern 200 and the pinning layer 112A. Further, a second light shield pattern 206 may be formed between the dummy pattern 200 and the second dummy pattern 132 to pass through the second silicon oxide layer 146.

FIG. 6 is a schematic enlarged cross-sectional view illustrating still another example of the second light shield pattern according to an embodiment of the present disclosure.

Referring to FIG. 6, a second light shield pattern 210 extending from the first edge portion of the light shield layer 150 toward the substrate 102 may be formed. In particular, the second light shield pattern 210 may be formed to pass through the insulating layer 140. That is, the second light shield pattern 210 may be disposed on the pinning layer 112A of the adjacent image cell 106A, and may be formed on the anti-reflective layer 148 to pass through the first oxide layer 142, the nitride layer 144 and the second oxide layer 146.

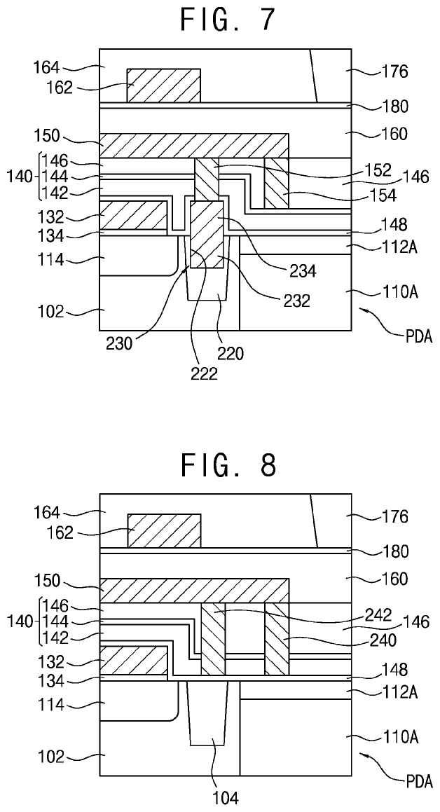

FIG. 7 is a schematic enlarged cross-sectional view illustrating still another example of the dummy pattern according to an embodiment of the present disclosure.

Referring to FIG. 7, an isolation region 220 and a dummy pattern 230 may be formed between the charge storage region 114 and the photodiode PDA of the adjacent image cell 106A. In particular, the dummy pattern 230 may include a lower pattern 232 disposed in the isolation region 220, and an upper pattern 234 disposed on the lower pattern 232. In embodiments, after the isolation region 220 is formed in a surface portion of the substrate 102, a trench 222 may be formed in the isolation region 220. Further, an impurity-doped polysilicon layer (not shown) may be formed to fill the trench 222, and then the dummy pattern 230 may be formed by patterning the polysilicon layer.

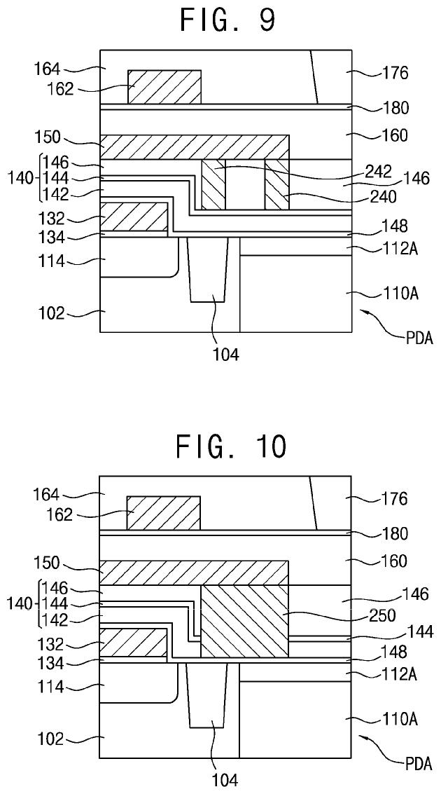

FIG. 8 is a schematic enlarged cross-sectional view illustrating still another example of the light shield pattern and the second light shield pattern according to an embodiment of the present disclosure. FIG. 9 is a schematic enlarged cross-sectional view illustrating still another example of the light shield pattern and the second light shield pattern according to an embodiment of the present disclosure.

Referring to FIG. 8, a first light shield pattern 240 may be formed between the first edge portion of the light shield layer 150 and the edge portion of the photodiode PDA of the adjacent image cell 106A, and a second light shield pattern 242 may be formed between the light shield layer 150 and the isolation region 104. In particular, the first and second light shield patterns 240 and 242 may be formed through the insulating layer 140 and may be used to prevent light from entering the charge storage region 114 from the adjacent image cell 106A. That is, the first and second light shield patterns 240 and 242 may be formed on the anti-reflective layer 148 to pass through the first oxide layer 142, the nitride layer 144 and the second oxide layer 146. Alternatively, as shown in FIG. 9, the first and second light shield patterns 240 and 242 may be formed on the nitride layer 144 to pass through the second oxide layer 146.

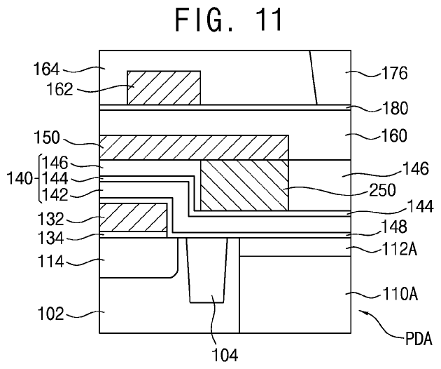

FIG. 10 is a schematic enlarged cross-sectional view illustrating still another example of the light shield pattern according to an embodiment of the present disclosure. FIG. 11 is a schematic enlarged cross-sectional view illustrating still another example of the light shield pattern according to an embodiment of the present disclosure.

Referring to FIG. 10, a light shield pattern 250 for inhibiting light from entering the charge storage region 114 from the adjacent image cell 106A may be formed between an edge portion of the light shielding layer 150 and the substrate 102. The light shield pattern 250 may have a relatively wide width. For example, a portion of the light shield pattern 250 may be disposed between the light shield layer 150 and an edge portion of the photodiode PDA of the adjacent image cell 106A, and another portion of the light shield pattern 250 may be disposed between the light shield layer 150 and the isolation region 104. Further, the light shield pattern 250 may be formed through the insulating layer 140. That is, the light shield pattern 250 may be formed on the anti-reflective layer 148 to pass through the first oxide layer 142, the nitride layer 144 and the second oxide layer 146. Alternatively, as shown in FIG. 11, the light shield pattern 250 may be formed on the nitride layer 144 to pass through the second oxide layer 146.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

What is claimed is:

1. An image sensor comprising:
a plurality of image cells, at least one image cell of the plurality of image cells comprising:
a photodiode disposed in a substrate;
a charge storage region disposed in the substrate to be spaced apart from the photodiode;
a transfer gate electrode disposed on a channel region between the photodiode and the charge storage region to transfer a charge from the photodiode to the charge storage region; and
a dummy pattern disposed on the substrate and configured to inhibit light from being introduced into the charge storage region from an adjacent image cell of the plurality of image cells.

2. The image sensor of claim 1, wherein the dummy pattern is disposed on a surface portion of the substrate between the charge storage region and a photodiode of the adjacent image cell and is made of the same material as the transfer gate electrode.

3. The image sensor of claim 1, wherein the dummy pattern comprises polysilicon.

4. The image sensor of claim 1, wherein the at least one image cell further comprises:
an insulating layer disposed on the substrate, the transfer gate electrode, and the dummy pattern; and
a light shield layer disposed on the insulating layer and configured to inhibit light from entering the charge storage region.

5. The image sensor of claim 4, wherein the at least one image cell further comprises:
a light shield pattern disposed between the dummy pattern and the light shield layer and configured to pass through the insulating layer.

6. The image sensor of claim 5, wherein the at least one image cell further comprises:
a second light shield pattern extending from a first edge portion of the light shield layer adjacent to the adjacent image cell toward the substrate.

7. The image sensor of claim 6, wherein the insulating layer comprises:
a first oxide layer disposed on the substrate, the transfer gate electrode, and the dummy pattern;
a nitride layer disposed on the first oxide layer; and
a second oxide layer disposed on the nitride layer,
wherein the second light shield pattern is configured to pass through the second oxide layer.

8. The image sensor of claim 6, wherein the at least one image cell further comprises:
an anti-reflective layer disposed between the substrate and the insulating layer,
wherein the second light shield pattern is configured to pass through the insulating layer.

9. The image sensor of claim 5, wherein the at least one image cell further comprises:
a third light shield pattern extending from a second edge portion of the light shield layer adjacent to the photodiode toward the substrate.

10. The image sensor of claim 5, wherein the at least one image cell further comprises:
a second light shield pattern disposed between the dummy pattern and the light shield layer and configured to pass through the insulating layer.

11. The image sensor of claim 4, wherein the at least one image cell further comprises:
a light shield pattern disposed between the dummy pattern and a first edge portion of the light shield layer adjacent to the adjacent image cell and configured to pass through the insulating layer.

12. The image sensor of claim 4, wherein the at least one image cell further comprises:
a second insulating layer disposed on the insulating layer and the light shield layer;
interlayer insulating layers disposed on the second insulating layer;
metal wiring layers disposed among the interlayer insulating layers; and
a light guide pattern passing through the interlayer insulating layers and corresponding to the photodiode.

13. The image sensor of claim 12, wherein the at least one image cell further comprises:
an etch stop layer disposed on the second insulating layer,
wherein the light guide pattern is disposed on the etch stop layer.

14. The image sensor of claim 1, wherein the at least one image cell further comprises:
an isolation region disposed in a surface portion of the substrate between the charge storage region and a photodiode of the adjacent image cell.

15. The image sensor of claim 14, wherein the dummy pattern is disposed on the isolation region.

16. The image sensor of claim 14, wherein the dummy pattern comprises a lower pattern disposed in the isolation region, and an upper pattern disposed on the lower pattern.

17. The image sensor of claim 1, wherein the at least one image cell further comprises:
a second dummy pattern disposed on the charge storage region and configured to inhibit light from entering the charge storage region; and
an insulating layer disposed between the charge storage region and the second dummy pattern and configured to electrically insulate the charge storage region from the second dummy pattern.

18. The image sensor of claim 17, wherein the second dummy pattern is made of a same material as the dummy pattern.

19. An image sensor comprising:
a photodiode disposed in a substrate;
a charge storage region disposed in the substrate to be spaced apart from the photodiode;
a transfer gate electrode disposed on a channel region between the photodiode and the charge storage region to transfer a charge from the photodiode to the charge storage region;
a light absorption pattern disposed on the substrate and configured to absorb light directed to the charge storage region from an adjacent image cell; and
a light reflection pattern disposed on the light absorption pattern and configured to reflect the light.

20. An image sensor comprising:
a plurality of image cells, at least one image cell of the plurality of image cells comprising:
a photodiode disposed in a substrate;
a charge storage region disposed in the substrate to be spaced apart from the photodiode;
a transfer gate electrode disposed on a channel region between the photodiode and the charge storage region to transfer a charge from the photodiode to the charge storage region;
an isolation region disposed in a surface portion of the substrate between the charge storage region and a photodiode of an adjacent image cell of the plurality of image cells;
an insulating layer disposed on the substrate;
a light shield layer disposed on the insulating layer and configured to inhibit light from entering the charge storage region;
a first light shield pattern disposed between an edge portion of the light shield layer and an edge portion of the photodiode of the adjacent image cell and configured to inhibit light from entering the charge storage region from the adjacent image cell; and
a second light shield pattern disposed between the light shield layer and the isolation region and configured to inhibit light from entering the charge storage region from the adjacent image cell.

21. The image sensor of claim 20, wherein the at least one image cell further comprises:
an anti-reflective layer disposed between the substrate and the insulating layer,
wherein the first light shield pattern and the second light shield pattern pass through the insulating layer and are disposed on the anti-reflective layer.

22. The image sensor of claim 20, wherein the insulating layer comprises:
a first oxide layer disposed on the substrate;
a nitride layer disposed on the first oxide layer; and
a second oxide layer disposed on the nitride layer,
wherein the first light shield pattern and the second light shield pattern pass through the second oxide layer and are disposed on the nitride layer.

23. An image sensor comprising:
a plurality of image cells, at least one image cell of the plurality of image cells comprising:
a photodiode disposed in a substrate;
a charge storage region disposed in the substrate to be spaced apart from the photodiode;
a transfer gate electrode disposed on a channel region between the photodiode and the charge storage region to transfer a charge from the photodiode to the charge storage region;
an isolation region disposed in a surface portion of the substrate between the charge storage region and a photodiode of an adjacent image cell of the plurality of image cells;
an insulating layer disposed on the substrate;
a light shield layer disposed on the insulating layer and configured to inhibit light from entering the charge storage region; and
a light shield pattern disposed between the substrate and the light shield layer and configured to inhibit light from entering the charge storage region from the adjacent image cell.

24. The image sensor of claim 23, wherein a portion of the light shield pattern is disposed between the light shield layer and an edge portion of the photodiode of the adjacent image cell, and another portion of the light shield pattern is disposed between the light shield layer and the isolation region.

25. The image sensor of claim 23, wherein the at least one image cell further comprises:
an anti-reflective layer disposed between the substrate and the insulating layer,
wherein the light shield pattern passes through the insulating layer and is disposed on the anti-reflective layer.

26. The image sensor of claim 23, wherein the insulating layer comprises:
a first oxide layer disposed on the substrate;
a nitride layer disposed on the first oxide layer; and
a second oxide layer disposed on the nitride layer,
wherein the light shield pattern passes through the second oxide layer and is disposed on the nitride layer.
